(19) United States
(12) Patent Application Publication
(10) Pub. No.: US 2009/0274537 A1
(43) Pub. Date: Nov. 5, 2009

(54) Suspension apparatus and exposure apparatus

(75) Inventor: Noriya Kato, Annaka-shi (JP)

Correspondence Address: OLIFF & BERRIDGE, PLC, P.O. BOX 320850, ALEXANDRIA, VA, 22320-4850, US

(73) Assignee: NIKON CORPORATION, TOKYO (JP)

(21) Appl. No.: 12/230,848

(22) Filed: Sep. 5, 2008

Related U.S. Application Data
(60) Provisional application No. 60/960,301, filed on Sep. 25, 2007.

(30) Foreign Application Priority Data
Sep. 7, 2007 (JP) 2007-232947

(51) Int. Cl. H01L 21/677; H01L 21/027

(52) U.S. Cl. 414/217.1

(57) ABSTRACT

A suspension apparatus includes a linking component which is used to suspend and support an object. The linking component has a first member which is connected to the object, and a second member which is linked to the first member, and the first member and the second member are linked together such that a relative position of each in a first direction is regulated, while relative movement between the first member and the second member in a second direction which is different from the first direction is possible.

### CROSS-REFERENCE TO RELATED APPLICATION

This application is a non-provisional application claiming priority to and the benefit of U.S. provisional application No. 60/960,301, filed Sep. 25, 2007. Furthermore, this application claims priority to Japanese Patent Application No. 2007-232947, filed Sep. 7, 2007. The entire contents of which are incorporated herein by reference.

### BACKGROUND

1. Field of the Invention

The present invention relates to a suspension apparatus and exposure apparatus.

2. Related Art

In a lithographic process to manufacture a semiconductor device or a liquid crystal display element or the like, an exposure apparatus such as a step-and-repeat reduction projection exposure apparatus (known as ‘stepper’), and a step-and-scan scanning projection apparatus (known as ‘scanning stepper’) are used. These types of exposure apparatus have a mask stage which supports a mask, a projection optical system which projects a pattern which is formed on the mask, and a substrate stage which supports a substrate, and transfer the mask pattern onto the substrate via the projection optical system while sequentially moving the mask stage and the substrate stage.

Among projection optical systems which are provided in an exposure apparatus, there are known those having a structure whereby they are supported by being suspended from a frame component on the outside of the exposure apparatus (for example, see PCT International Publication No. WO 2006/038952). Chains and rods, for example, and the like are employed as the suspension component which suspends the projection optical system. By changing the position and tilt of the suspension component, it is possible to make fine adjustments to the position of the projection optical system.

If a chain is employed as the suspension component, rust may easily be formed and string vibration may easily be generated. Moreover, if a rod is used as the suspension component, then although it is more difficult for rust and string vibration to be generated compared with when a chain is used, a considerable degree of control is relatively required, when fine adjustments are made to the position of the projection optical system.

A purpose of some aspects of the present invention is to provide a suspension apparatus and an exposure apparatus which are superior in efficiency of object position control and in anti-vibration performance.

### SUMMARY

A first aspect of the present invention provides a suspension apparatus (10) which comprises a linking component which is used to suspend and support an object. The linking component has a first member which is connected to the object, and a second member which is linked to the first member, and the first member and the second member are linked together such that the relative position of each along a first direction is regulated, while relative movement between the first member and the second member along a second direction which is different from the first direction is possible.

According to the first aspect, it is possible to maintain the rigidity of the linking component overall at a low level. This is advantageous for reduction of the amount of control required when the object is being moved a fixed distance, and for suppression of vibration transmission. AS a result, efficiency of object position control and anti-vibration performance can be enhanced.

A second aspect of the present invention provides an exposure apparatus provided with the above described object suspension apparatus.

According to the second aspect, it is possible in this exposure apparatus to obtain an improvement in the reliability of the control of an object which is being suspended, and keep to a minimum the effects of vibration. Because of this, it is possible to obtain an improvement in exposure accuracy.

### BRIEF DESCRIPTION OF THE DRAWINGS

FIG. 1 is a cross-sectional view showing the structure of an exposure apparatus according to a first embodiment of the present invention.

FIG. 2 is a plan view showing a placement of a suspension apparatus according to the present embodiment.

FIG. 3 is a cross-sectional view showing the structure of the object suspension apparatus according to the present embodiment.

FIG. 4 is a cross-sectional view showing the structure of a portion of the object suspension apparatus according to the present embodiment.

FIG. 5 is a cross-sectional view showing the structure of the object suspension apparatus according to the present embodiment.

FIG. 6 is a cross-sectional view showing the structure of an air mount according to the present embodiment.

FIG. 7 is a cross-sectional view showing the structure of a portion of an exposure apparatus according to a second embodiment of the present invention.

FIG. 8 is a perspective view showing the structure of another object suspension apparatus of the present embodiment.

FIG. 9 is a flowchart showing an example of a manufacturing process for a micro device.

FIG. 10 is a view showing an example of specific processes of Step S13 shown in FIG. 9.

### DESCRIPTION OF EMBODIMENTS

Embodiments of the present invention will now be described with reference made to the drawings.

### First Embodiment

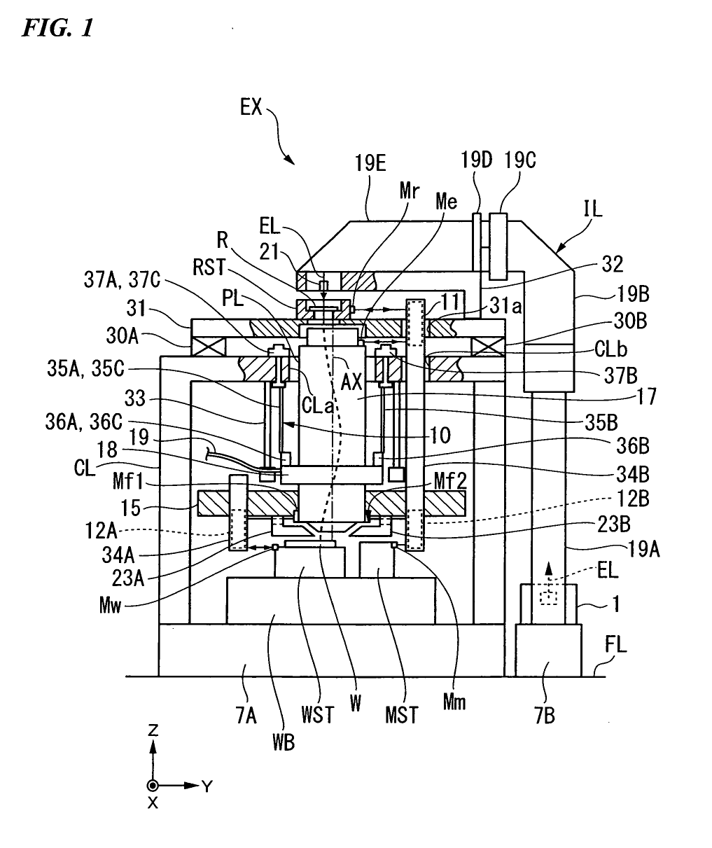

FIG. 1 shows the schematic structure of an exposure apparatus EX according to a first embodiment of the present invention.

The exposure apparatus EX shown in FIG. 1 is a step-and-scan type of scanning exposure apparatus which transfers patterns which are formed on a reticle R onto each shot area on a wafer W while moving the reticle R and the wafer W in synchronization in a one-dimensional direction, namely, is what is known as a scanning stepper.

In the description given below, where necessary, an XYZ rectangular coordinate system is set in the drawings, and positional relationships between the respective components are described while making reference to this XYZ rectangular coordinate system. The XYZ rectangular coordinate system shown in FIG. 1 is set such that the X axis and the Y axis are contained within a plane which is parallel to the movement plane of the wafer W, and the Z axis is set in a direction which follows an optical axis AX of the projection optical system PL. Moreover, in the present embodiment, the direction in which the reticle R and the wafer W are moved in synchronization (i.e., the scan direction) is set to the Y direction.

This exposure apparatus EX is mounted on a floor surface FL via large and small pedestals 7A and 7B, and includes an illumination optical system IL which illuminates the reticle R using exposure light EL, a reticle stage RST which is able to move while holding the reticle R, a projection optical system PL which projects the exposure light EL which has been emitted from the reticle R onto a wafer W, a wafer stage WST which is able to move while holding the wafer W, a measurement stage MST, and a main column CL on which the wafer stage WST is mounted and which holds the projection optical system PL and the like. The exposure apparatus EX also has a control unit (not shown) which collectively controls the exposure apparatus EX.

The illumination optical system IL is an optical system which illuminates the reticle R which is supported on the reticle stage RST with the exposure light EL. This illumination optical system IL has a uniformizing optical system which uniformizes the illumination intensity of the exposure light EL which is emitted from an exposure light source 1 which is provided on the small pedestal 7B, a beam splitter, a variable light attenuator for adjusting the amount of light, mirrors, a relay lens system (these are placed inside illumination system chambers 19A and 19B), a reticle blind (placed at an exit end 19C and an entry end 19D) which sets the illumination area on the reticle R which is illuminated by the exposure light EL to a slit shape, and a focusing lens system (placed inside an illumination chamber 19E). The illumination optical system IL is able to illuminate a predetermined illumination area on the reticle R with exposure light EL having a more uniform illumination intensity distribution. Ultraviolet light such as ultraviolet region emission lines (g-lines, h-lines, and i-lines) which are emitted, for example, from a mercury lamp, KrF excimer laser light (having a wavelength of 248 nm), and ArF excimer laser light (having a wavelength of 193 nm) and the like can be used for the exposure light EL emitted from the exposure light source.

The reticle stage RST is supported on top of a reticle base 31 via air bearings (not shown), and is a stage apparatus which, while supporting the reticle R, performs two-dimensional movements within an XY plane which is perpendicular to the optical axis AX of the projection optical system PL, and also adjusts the angle of rotation thereof in the Z direction. The position in the XY direction and also the angle of rotation in the Z direction of the reticle R which is supported on the reticle stage RST are measured in real time by a laser interferometer 11, a movement mirror Mr and a reference mirror Me, and results from these measurements are output to a control unit (not shown). A drive system (not shown) which is formed, for example, by a linear motor or the like is provided on the reticle stage RST, and, as a result of the control unit controlling this drive system based on measurement results from the laser interferometer 11, positioning of the reticle R which is supported on the reticle stage RST is conducted. The reticle base 31 is supported on the main column CL via anti-vibration apparatuses 30A and 30B. A column 32 which supports the illumination system chamber 19E is provided on the reticle base 31. An aperture portion through which the exposure light EL which has been emitted from the illumination system chamber 19E passes is provided in a distal end of the column 32, and a pair of alignment systems 21 are provided in both end portions in the X direction relative to the optical path of the exposure light EL inside this aperture portion. A recessed portion which is used to house a top portion of the projection optical system PL is formed in a bottom surface of a central portion of the reticle base 31, and an aperture portion through which the exposure light EL passes is formed in this recessed portion.

The projection optical system PL is an optical system which projects and exposes a pattern which is formed on a reticle R onto a wafer W at a predetermined projection magnification, and is constructed by housing a plurality of optical elements inside a lens barrel 17. A top portion of the projection optical system PL passes through the inside of an aperture portion CLa in the top portion of the main column CL, and is housed in the recessed portion of the reticle base 31. In the present embodiment, the projection optical system PL is a reduction system in which the projection ratio β is, for example, 1/4 or 1/5. This projection optical system PL may also be either an equal magnification system or an enlargement system. A planar measurement mount 15 which is circular when seen in plan view, for example, is fixed to the lens barrel 17 on a bottom end side (i.e., on the downstream side of the exposure light EL) of the lens barrel 17. A sensor column 34A which holds a laser interferometer 12A, a sensor column 34B which holds the laser interferometer 11 and a laser interferometer 12B, and an alignment system (not shown) and the like are fixed to the measurement mount 15. The sensor column 34B penetrates the interior of an aperture portion CLb in a top portion of the main column CL, and is positioned such that a top end thereof penetrates the interior of an aperture portion 31a of the reticle base 31 and protrudes above the reticle base 31. A projection optical system 23A which projects a slit image onto a plurality of measurement points on the surface of the wafer W, and a projection optical system 23B which receives reflected light from this surface and detects information relating to the amount of sideways shift of the reconfigured slit image are fixed to a bottom surface of the measurement frame 15.

A planar frame portion 18 which is rectangular when seen in plan view, for example, is provided above the measurement mount 15 of the lens barrel 17. The frame portion 18 is connected to three linking components 35A to 35C. Bottom ends of the linking component 35A to 35C are connected to the frame component 18, while top ends of the linking components 35A to 35C are connected to the main column CL. In this manner, the projection optical system P1 which includes the frame portion 18 and the lens barrel 17 is suspended from the main column CL by the three linking components 35A to 35C so as to be in a three-point suspension state. Position adjustment apparatuses 36A to 36C which adjust the linking positions of the respective linking components 35A to 35C are provided on the frame portion 18, and the aforementioned three linking components 35A to 35C are connected to the frame portion 18 via these position adjustment apparatuses 36A to 36C.

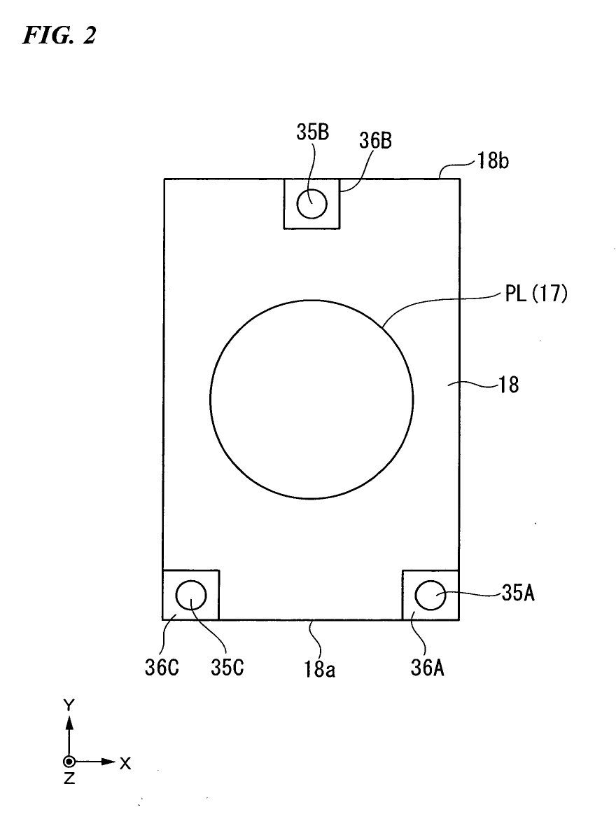

FIG. 2 is a plan view showing the layout of the linking components 35A to 35C and the position adjustment apparatuses 36A to 36C on the frame portion 18.

The position adjustment component 36A and the position adjustment component 36C are located in positions along a first side (for example, the bottom side in the drawings) 18a of the frame component 18. Of these, the position adjustment component 36A is located at one end of the first side 18a (for example, at the right end in the X direction in the drawings), and the position adjustment component 36B is located at another end of the first side (for example, at the left end in the X direction in the drawings). The position adjustment component 36B is located at a position along a second side (for example, the top side in the drawings) 18b which faces the first side 18a, and in the center in the X direction of the second side 18b.

The linking component 35A is connected to the position adjustment component 36A, the linking component 35B is connected to the position adjustment component 36B, and the linking component 35C is connected to the position adjustment component 36C. By arranging the layout on an XY plane of the linking components 35A to 35C and the position adjustment components 36A to 36C in the manner described above, the frame portion 18 is able to be easily moved in all directions within the XY plane.

Returning to FIG. 1, air mounts 37A to 37C are provided respectively at points of connection between the linking components 35A to 35C and the top portion of the main column CL, and each of the linking components 35A to 35C is connected to the main column CL via the relevant air mount 37A to 37C.

In this manner, in the present embodiment, a suspension apparatus 10 is formed by the projection optical system PL serving as an object, the linking components 35A to 35C, the position adjustment components 36A to 36C, and the air mounts 37A to 37C.

A column 33 which extends in the Z direction is fixed to three locations on the bottom surface of the top portion of the main column CL. A non-contact type of six-degrees-of-freedom positioning apparatus is provided between the column 33 and the frame portion 18 of the projection optical system PL. In addition, a wiring bundle 19 which transmits electrical signals is attached to the frame portion 18.

The wafer stage WST is supported by air bearings on a wafer surface plate WB, and is guided so as to be able to move within an XY plane while holding the wafer W. The wafer stage WST is able to be moved in three degree of freedom directions, namely, the X direction, the Y direction, and the OZ direction by a linear motor (not shown). The position of the wafer stage WST in the X direction, the Y direction, and the OZ direction are measured in real time by the laser interferometer 12A, a movable mirror Mw, and a reference mirror Mf1, and results from these measurements are output to a control unit.

In the same way as the wafer stage WST, the measurement stage MST is supported by air bearings on the wafer surface plate WB, and is supported and guided so as to be able to be moved within an XY plane over the wafer surface board WB by a linear motor (not shown). The position of the measurement stage MST in the X direction, the Y direction, and the OZ direction are measured in real time by the laser interferometer 12B, a movable mirror Mm, and a reference mirror Mf2, and results from these measurements are output to a control unit.

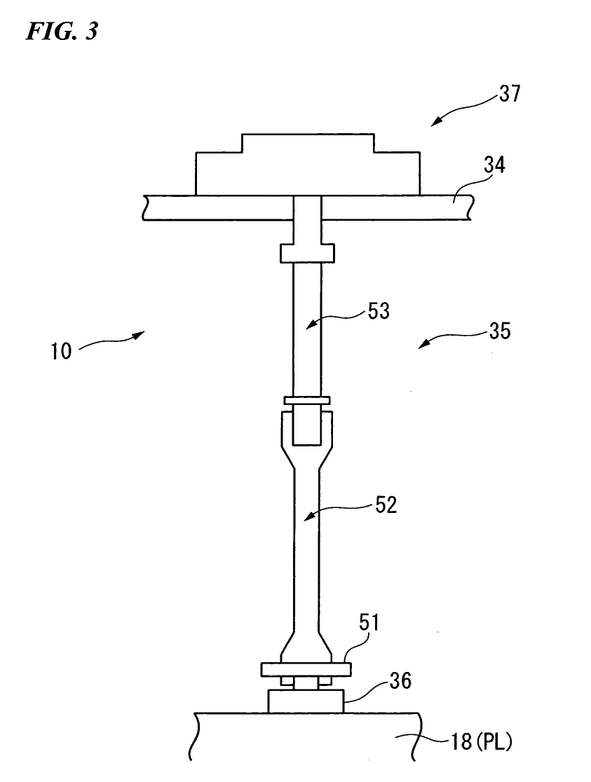

FIG. 3 is a view schematically showing the structure of the suspension apparatus 10. Hereinafter, when describing the structure of the suspension apparatus 10, one group made up of a linking component, position adjustment component, and air mount from among the above described three groups of linking components 35A to 35C, position adjustment components 36A to 36C, and air mounts 37A to 37C is described as an example. In this case, the respective portions are denoted as the ‘linking component 35’, the ‘position adjustment component 36’, and the ‘air mount 37’.

As is shown in FIG. 3, the linking component 35 has a first member 51, a second member 52, and a third member 53. These first member 51, second member 52, and third member 53 are rigid bodies which are formed, for example, from metal or the like. A bottom end of the first member 51 is connected to the position adjustment apparatus 36, and a top end of the first member 51 and a bottom end of the second member 52 are linked together. In addition, a top end of the second member 52 and a bottom end of the third member 53 are linked together, and a top end of the third member 53 is connected to the air mount 37. Moreover, actuators (not shown) are attached respectively to each of the first member 51, the second member 52, and the third member 53 making it possible for the positions of each of these components to be adjusted independently via signals from the control unit.

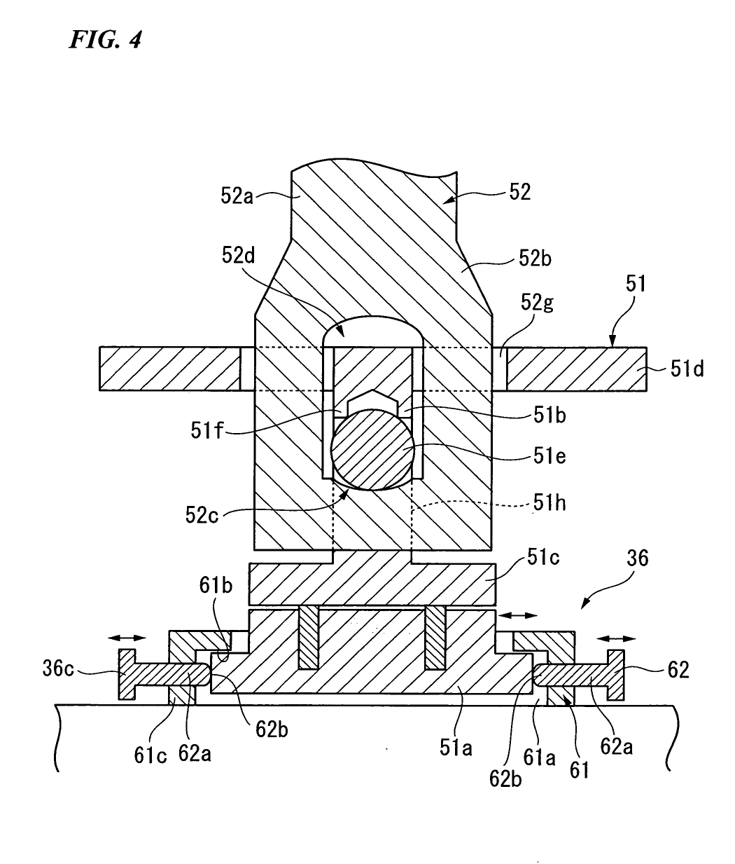

FIG. 4 is a schematic cross-sectional view showing the structure of the position adjustment apparatus 36 and the structure of the linking component 35 in the vicinity of this position adjustment apparatus 36.

As is shown in FIG. 4, the first member 51 has a base 51a which is provided inside the position adjustment apparatus 36, a linking portion 51b which allows the second member 52 to be linked, a connecting portion 51c which connects the base 51a to the linking portion 51b, a flange 51d which is provided on a top portion of the linking portion 51b, and a spherical surface component 51e which is provided inside the linking portion 51b. The base 51a and the linking portion 51b are integrally connected by the connecting portion 51c, and the linking portion 51b moves in conjunction with the movement of the base 51a. A through hole 51g and a through hole 51h which allow a portion of the second member 52 to penetrate therethrough are provided in the flange 51d and the linking portion 51b. The through hole 51g is provided with a fixed margin (i.e., gap) which extends in a perpendicular direction relative to the surface of the paper showing FIG. 3. The spherical surface component 51e is formed by a sphere having a predetermined diameter (taken as r1).

The second member 52 is formed by providing a circular portion 52b at a bottom end of a rod-shaped portion 52a. The circular portion 52b is joined to the first member 51 so as to penetrate the through hole 51g and the through hole 51h which are provided in the first member 51. A sliding bearing 52c is provided in the circular portion 52b. The sliding bearing 52c is provided with a spherical bearing surface which has a diameter r2 which is larger than the diameter r1 of the spherical member 51e. When the circular portion 52b is joined to the first member 51, the sliding bearing 52c supports the spherical member 51e. At this time, because the diameter r2 of the sliding bearing 52c is larger than the diameter r1 of the spherical member 51e, the spherical member 51e and the sliding bearing 52c are in contact at one point (i.e., are in point contact). At this time, the spherical member 51e and the sliding bearing 52c are able to function as a spherical rolling structure. Moreover, it is also possible for them to function not as a spherical rolling structure, but as a spherical sliding structure.

When the first member 51 and the second member 52 are moved relatively to each other by the actuators (not shown), the first member 51 and the second member 52 rotate (or oscillate) in all directions including rotation directions (i.e., oscillation in the left-right direction in FIG. 3 (i.e., a second direction) and oscillation in a direction perpendicular to the paper surface showing FIG. 3 (i.e., a second direction)) centering on the contact point between the spherical member 51e and the sliding bearing 51c. Because there is a contact point between the spherical member 51e and the sliding bearing 51c, contact resistance during rotational movement is reduced, and there is a reduction in the rigidity of the linking component 35 overall in this rotation direction. When the first member 51 and the second member 52 are linked together, a gap 52d is formed between the circular portion 52b and the flange 51d. This gap 52d is the margin when the first member 51 and the second member 52 are moving relatively to each other.

As has been described above, by linking together the first member 51 and the second member 52, the relative positions are prescribed between the first member 51 and the second member 52 in an up-down direction in FIG. 3 (i.e., in a first direction). Moreover, relative movement between the first member 51 and the second member 52 is possible in directions which are different from this first direction, for example, in directions which include a left-right direction in FIG. 3 (i.e., in a second direction) and a direction which is perpendicular to the surface of the paper showing FIG. 3 (i.e., in a second direction). Accordingly, the first member 51 can be displaced relative to the second member 52 by, for example, an actuator or the like (not shown).

Moreover, as is shown in FIG. 4, the position adjustment apparatus 36 has a holding component 61 which has a rectangular shape when seen in plan view, and position adjustment components 62 which are formed, for example, by screws or the like, and which are provided individually on each side of the holding component 61 when seen in plan view. In FIG. 4, the position adjustment components which are provided in directions perpendicular to the surface of the paper (i.e., the screws on the far side and on the near side in a direction perpendicular to the surface of the paper) have been omitted from the drawing.

The holding component 61 is fixed to the frame portion 18 such that the relative positions between the holding component 61 and the frame portion 18 are not changed by the application of external force. A housing portion 61a which houses the base 51a is provided inside this holding component 61, and the base 51a is held on a ceiling portion 61b. The dimensions of the housing portion 61a are larger compared to the dimensions of the base 51a, so that when the base 51a is being housed, a gap exists between the base 51a and side portions 61c of the holding component 61.

Each position adjustment component 62 has a threaded portion 62a on which thread ridges are formed, and these threaded portions 62a are screwed into the side portions 61c of the holding component 61. The length of the threaded portions 62a (i.e., the dimension in the left-right direction in the drawing of the position adjustment components 62) is greater than the thickness of the side portions 61c, so that the threaded portions 62a are able to penetrate the side portions 61c of the holding component 61.

Distal ends 62b of the respective position adjustment components 62 abut against the base 51a, and in this state, the base 51a is not able to move in the left-right direction in the drawing or in a direction perpendicular to the surface of the paper. By rotating the respective position adjustment components 62, the position of the distal end 62b of the position adjustment component 62 is moved. In the case of the two position adjustment components 62 shown in FIG. 4, by rotating the position adjustment components 62, the positions of the distal ends 62b are moved in the left-right directions seen in the drawings. By rotating the respective position adjustment components 62 and thereby adjusting the positions of the distal ends 62b thereof, the position of the base 51a relative to the holding component 61, namely, the position of the base 51a relative to the frame portion 18 can be adjusted in the left-right direction seen in the drawing and in a direction perpendicular to the surface of the paper.

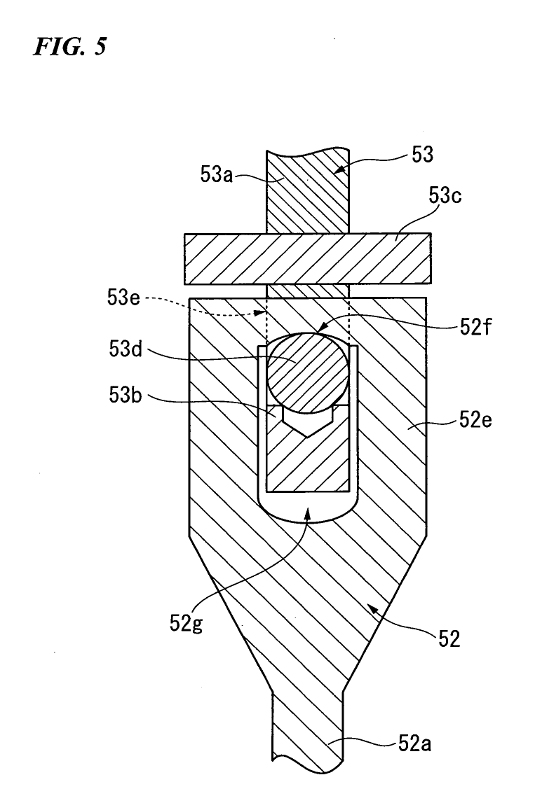

FIG. 5 is a cross-sectional view showing the structure of a linkage between the second member 52 and the third member 53.

As is shown in FIG. 5, the third member 53 has a rod-shaped portion 53a which is connected to the air mount 37, a linking portion 53b which is linked to the second member 52, a flange 53c which is provided above the linking portion 53b, and a spherical surface component 53d which is provided inside the linking portion 53b. A through hole 53e which allows a portion of the second member 52 to penetrate therethrough is provided in the linking portion 53b. The spherical surface component 53d is formed by a sphere having a predetermined diameter (taken as r3).

The second member 52 is formed by providing a circular portion 52e at a top end of a rod-shaped portion 52a. The circular portion 52e is joined to the third member 53 so as to penetrate the through hole 53e which is provided in the third member 53. A sliding bearing 52f is provided in the circular portion 52e. The sliding bearing 52f is provided with a spherical bearing surface which has a diameter r4 which is larger than the diameter r3 of the spherical member 53d. When the circular portion 52e is joined to the third member 53, the sliding bearing 52f supports the spherical member 53d. Because the diameter r4 of the sliding bearing 52f is larger than the diameter r3 of the spherical member 53d, the spherical member 53d and the sliding bearing 52f are in contact at one point (i.e., are in point contact). At this time, the spherical member 53d and the sliding bearing 52f are able to function as a spherical rolling structure. Moreover, it is also possible for them to function not as a spherical rolling structure, but as a spherical sliding structure.

When the second member 52 and the third member 53 are moved relatively to each other by the actuators (not shown), the second member 52 and the third member 53 rotate in rotation directions (i.e., the left-right direction in FIG. 4 (i.e., a second direction) and a direction perpendicular to the paper surface showing FIG. 4 (i.e., a second direction)) centering on the contact point between the spherical member 53d and the sliding bearing 52f. Because there is a contact point between the spherical member 53d and the sliding bearing 52f, contact resistance during rotational movement is reduced, and there is a reduction in the rigidity of the linking component 35 overall in this rotation direction. When the second member 52 and the third member 53 are linked together, a gap 52g is formed between the circular portion 52e and the linking portion 53b. This gap 52g is the margin when the second member 52 and the third member 53 are moving relatively to each other.

As has been described above, by linking together the second member 52 and the third member 53, the relative positions are prescribed between the second member 52 and the third member 53 in an up-down direction in FIG. 4 (i.e., in a first direction). Moreover, relative movement between the second member 52 and the third member 53 is possible in directions which are different from this first direction, for example, in directions which include a left-right direction in FIG. 5 (i.e., in a second direction) and a direction which is perpendicular to the surface of the paper showing FIG. 4 (i.e., in a second direction). Accordingly, the third member 53 can be displaced relative to the second member 52 by, for example, an actuator or the like (not shown).

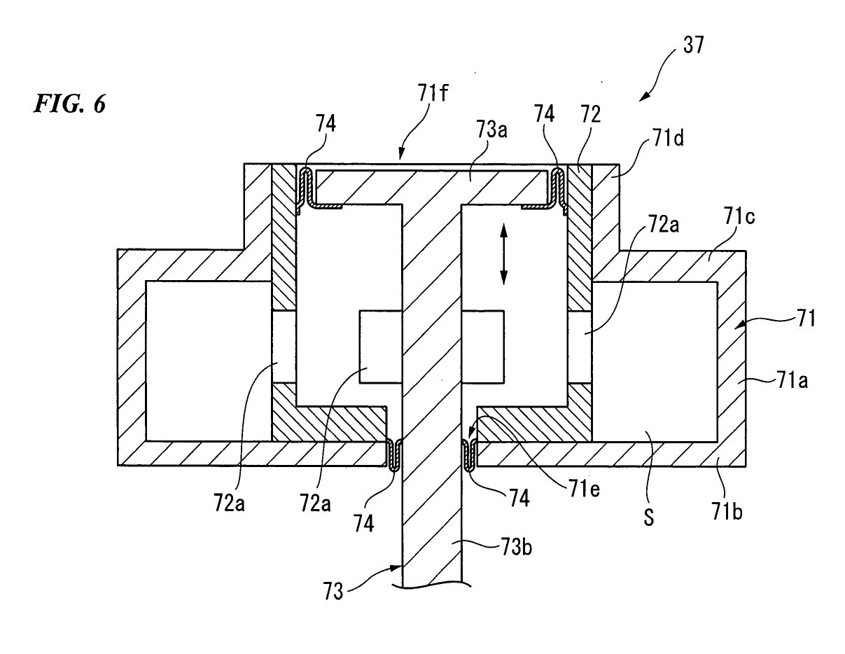

FIG. 6 is a schematic cross-sectional view showing the structure of the air mount 37.

As is shown in FIG. 6, the air mount 37 supports the linking component 35, and is provided with a space component 71 which internally forms a space S, a guide component 72 which is provided inside the housing member 71 so as to extend in the up-down direction (i.e., in a first direction) in FIG. 5, a movable member 73 which is supported so as to be able to move in the up-down direction in FIG. 5 following the guide component 72, and a sealing member 74 which seals off the space S. A pressure adjustment apparatus (not shown) which adjusts the pressure inside the space S is mounted on this air mount 37.

The housing member 71 has an exterior wall 71a which has, for example, a circular cylinder shape, a bottom portion 71b which closes off a portion of a bottom surface (i.e., the bottom side in the drawing) of the circular cylinder formed by this exterior wall 71a, a ceiling portion 71c which closes off a portion of a top surface (i.e., the top side in the drawing) of the circular cylinder, and a protruding portion 71d which extends upwards in the drawing from the ceiling portion 71c.

An aperture portion 71e is provided in a central portion when seen in plan view of the bottom portion 71b. An aperture portion 71f is provided in a central portion when seen in plan view of the ceiling portion 71c. The protruding portion 71d is formed around a circumferential edge of the aperture portion 71f.

The guide component 72 is a circular cylinder-shaped component which is provided so as to adhere tightly to the protruding portion 71d of the housing member 71. A through hole 72a which penetrates the guide component 72 is provided in the guide component 72. The space inside the circular cylinder of the guide component 72 and a space which is enclosed by the exterior wall 71a, the ceiling portion 71c, and the bottom portion 71b of the housing member 71 are connected to each other by the through hole 72a. These connected spaces correspond to the above described space S.

The movable member 73 is provided so as to be able to move in an up-down direction in FIG. 5 following the guide component 72, and has a lid portion 73a which, when seen in plan view, is formed so as to follow the inner diameter of the guide component 72, and a shaft portion 73b which is provided integrally with the lid portion 73a and which penetrates the space S so as to protrude to an outside portion of the housing member 71. A bottom end of the shaft portion 73b is integrally connected to the above described third member 53 (see FIG. 2).

The sealing member 74 is a film-shaped component which has flexibility and is formed, for example, from a resin and seals off the space S. This sealing member 74 is provided so as to close off the gap between the guide component 72 and the movable member 73. In addition, for example, on the aperture portion 71f side, it is adhered by an adhesive component (not shown) so as to block off the space between the lid portion 73a of the movable member 73 and the internal surface of the guide component 72, and is provided so as to bend upwards as seen in the drawing between the lid portion 73a and the guide component 72. In addition, for example, on the aperture portion 71e side, it is adhered by an adhesive component (not shown) between the shaft portion 73a of the movable member 73 and the guide component 72, and is provided so as to bend downwards as seen in the drawing between the shaft portion 73b and the guide component 72.

In this air mount 37, if the pressure inside the space S is changed by the pressure adjustment apparatus (not shown), the movable member 73 is moved in conjunction with this change in the pressure. For example, if the pressure inside the space S is reduced, the movable member 73 moves in a direction in which the space S is decreased, namely, downwards from the position shown in FIG. 5. For example, if the pressure inside the space S is increased, the movable member 73 moves in the direction in which the space S is expanded, namely, upwards from the position shown in FIG. 5.

Next an operation of the exposure apparatus EX which has the above described structure will be described.

Prior to an exposure operation, the position of the link between the frame portion 18 and the linking component 35 is adjusted. The wire bundle 19 shown in FIG. 1 is attached to the frame portion 18, and the frame portion 18 is placed in a state of receiving stationary thrust (i.e., constant thrust) by means of detention in the wiring bundle 19. When the frame portion 18 is in a state of receiving constant thrust, it is necessary for an actuator (not shown) to be driven in consideration of the effects of this constant thrust, so that it is difficult to make precise adjustments to the position of the frame portion 18. It is possible to drive the actuator so as to apply thrust to the frame in resistance to this constant thrust, however, in this case, there is a possibility that the heat generated by the actuator will have an adverse affect on surrounding portions. Moreover, considerable thrust force is required from the actuator so that a large-sized actuator is needed, and there is a possibility that sufficient space for the actuator to be installed will not be available. Therefore, in the structure shown in FIG. 4, the structure makes it possible to adjust the position of the connection between the frame portion 18 and the linking component 35 by means of the position adjustment component 62 of the position adjustment apparatus 36.

Specifically, the link position is adjusted such that, when the frame portion 18 is linked together with the linking component 35, the link position is offset relative to the perpendicular direction of the linking component 35. If the link position is offset relative to the perpendicular direction of the linking component 35, then due to the pendulum principle, a force acts which attempts to move the link portion of the frame portion 18 to a position in the perpendicular direction of the linking component 35. Accordingly, the link position between the frame portion 18 and the linking component 35 is adjusted to a position where this force and the above described constant thrust are counterbalanced, so that, to all appearances, the constant thrust is negated.

After the link position between the frame portion 18 and the linking component 35 has been adjusted, exposure processing using the exposure apparatus EX is performed. Specifically, the exposure light EL which is emitted from the exposure light source 1 is firstly shaped to the required size and illuminance uniformity by an illumination optical system IL which is formed by a variety of lenses and mirrors and the like. The shaped exposure light EL then illuminates a reticle R on which a pattern has been formed, and the pattern formed on the reticle R is then transferred in a reduced size via the projection optical system PL onto each shot area on a wafer W which is being held on the wafer stage WST. When the constant thrust acting on the frame portion 18 appears to be zero, then by driving an actuator (not shown), adjustment of the position of the frame portion 18 can be easily carried out. As a result, detailed patterns can be formed with a high level of accuracy on the wafer W.

In this manner, according to the present embodiment, the linking components 35A to 35C which are linked to the projection optical system PL have the first member 51 which is connected to the projection optical system PL, and the second member 52 which is linked to this first member 51. Moreover, this first member 51 and second member 52 are linked such that the relative positions thereof in the up-down directions of the exposure apparatus EX are regulated, and such that they can move relatively to each other in directions other than the up-down directions of the exposure apparatus EX. As a result, it is possible to keep the rigidity of the overall linking component 35 to a low level in directions other than the up-down directions of the exposure apparatus EX, while maintaining the rigidity thereof in the up-down direction of the exposure apparatus EX. By keeping the rigidity of the linking component 35 to a low level in directions other than the up-down directions of the exposure apparatus EX, it is possible to reduce the amount of control required when the projection optical system PL is being moved a fixed distance, and efficient control becomes possible. In addition, it is possible to improve the anti-vibration performance.

### Second Embodiment

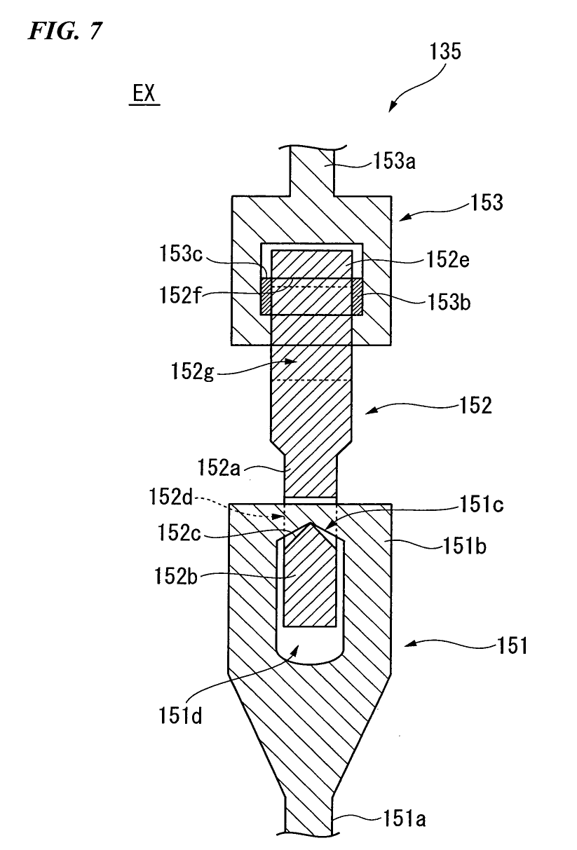

Next, a second embodiment of the present invention will be described. FIG. 7 is a cross-sectional view showing the structure of a linking component 135 according to the present embodiment. In the present embodiment, because the structure of the linking component 135 is different from the first embodiment, this description centers on this structure.

As is shown in FIG. 7, the linking component 135 has a first member 151, a second member 152, and a third member 153. In the same way as in the first embodiment, a bottom end of the first member 151 is connected to a position adjustment apparatus (not shown), and a top end of the third member 153 is connected to an air mount (not shown). Here, descriptions of the position adjustment apparatus and the air mount are omitted.

The first member 151 has a structure in which a circular portion 151b is provided on a top end of a rod-shaped portion 151a, and a bearing portion 151c is formed in the circular portion 151b. The bearing portion 151c is a recessed portion which is formed as an acute angle when seen in cross-sectional view, and a central portion thereof in the left-right direction in the drawing is the most recessed portion. This most recessed portion forms a straight line which extends in a direction which is perpendicular to the surface of the paper showing FIG. 7.

The second member 152 has a structure in which an engaging portion 152b is provided at a bottom end of a rod-shaped portion 152a, and a through hole 152d is provided above this engaging portion 152b. The engaging portion 152b is a convex portion whose top portion 152c is formed as an acute angle when seen in cross-sectional view, and a central portion thereof in the left-right direction in the drawing is the most protruding portion. This most protruding apex portion forms a straight line which extends in a direction which is perpendicular to the surface of the paper. Moreover, a circular portion 152e is provided on a top end of the rod-shaped portion 152a of the second member 152, and a bearing portion 152f is formed in the circular portion 152e so that the structure is the same as that of the top end of the first member 151. However, the top end of the second member 152 is formed in a direction which is offset by 90° from the top end of the first member 151 when seen in plan view.

The third member 153 has a structure in which an engaging portion 153b is provided at a bottom end of a rod-shaped portion 153a, and a through hole 153d is provided above this engaging portion 152b so that the structure is the same as that of the top end of the first member 151. However, the bottom end of the third member 153 is formed in a direction which is offset by 90° from the bottom end of the second member 152 when seen in plan view.

When the circular portion 151b of the first member 151 has been placed inside the through hole 152d which is provided above the engaging portion 152b of the second member 152, the engaging portion 152b is engaged in the bearing portion 151c. The slope of the bearing portion 151c of the first member 151 is less steep compared with the slope of the engaging portion 152b of the second member 152. In this manner, when the bearing portion 151c and the engaging portion 152b are in contact with each other along a straight line (i.e., are in linear contact), the first member 151 and the second member 152 are linked together.

When the first member 151 and the second member 152 are being moved relative to each other by an actuator (not shown), the first member 151 and the second member 152 are able to rotate (or oscillate) in a rotation direction (i.e., in a second direction) centered on the contact point between the bearing portion 151c and the engaging portion 152b. Because the contact between the two is linear contact, contact resistance during rotational movement is reduced, and the rigidity of the linking component 135 overall in this rotation direction can be held at a low level.

When the first member 151 and the second member 152 are linked together, a gap 151d is formed between the circular portion 151b and the engaging portion 152b. This gap 151d is the margin when the first member 151 and the second member 152 are moving relatively to each other.

As has been described above, by linking together the first member 151 and the second member 152, the relative positions are prescribed between the first member 151 and the second member 152 in an up-down direction in FIG. 6 (i.e., in a first direction). Moreover, relative movement between the first member 151 and the second member 152 is made possible by, for example, an actuator or the like (not shown) in directions which are different from this first direction, namely, in a left-right rotation direction in FIG. 6 (i.e., in a second direction).

The structure of the link between the second member 152 and the third member 153 is the same as the structure of the link between the first member 151 and the second member 152. However, the direction in which rotation is made possible by the link between the second member 152 and the third member 153 is offset by 90° from the direction in which rotation is made possible by the link between the first member 151 and the second member 152.

In this manner, according to the present embodiment, because the first member 151, the second member 152, and the third member 153 are linked together in linear contact, in the same way as in the first embodiment, it is possible to keep the rigidity of the overall linking component 135 to a low level in directions other than the up-down directions of the exposure apparatus EX, while maintaining the rigidity thereof in the up-down direction of the exposure apparatus EX. By keeping the rigidity of the linking component 135 to a low level in directions other than the up-down directions of the exposure apparatus EX, it is possible to reduce the amount of control required when the projection optical system is being moved a fixed distance, and efficient control becomes possible. In addition, it is possible to improve the anti-vibration performance.

Preferred embodiments of the present invention have been described above with reference made to the attached drawings, however, it is to be understood that the present invention is not limited to these embodiments. Configurations and combinations and the like of the respective component elements illustrated in the above embodiments are simply examples thereof, and various modifications may be made based on design requirements and the like insofar as they do not depart from the spirit or scope of the present invention.

For example, in the above described embodiments, the projection optical system PL is used as an example of an object forming the suspension apparatus 10, however, the present invention is not limited to this and it is of course possible for this object to be, for example, the laser interferometers (i.e., an interferometer) 11, 12A, and 12B, or the measurement mount (i.e., a measurement component) 15, or the like.

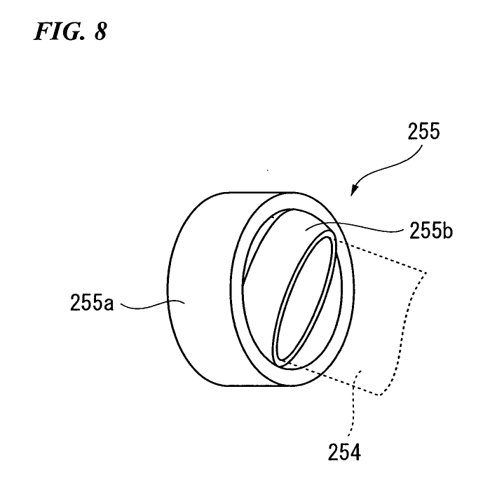

Moreover, in the above described first embodiment, a structure is employed in which point contact is obtained using spherical members and sliding bearings in the link portions between the first member 51, the second member 52, and the third member 53, however, the present invention is not limited to this combination, and it is also possible to employ a structure in which point contact is obtained using, for example, a conical engaging portion instead of the spherical member and using a bearing having a conical recessed portion instead of the sliding bearing. Moreover, as is shown in FIG. 8, it is also possible to use the structure of a conventional sliding bearing 255 which has an outer circular portion 255a (i.e., a spherical sliding bearing) and an inner circular portion (i.e., a spherical member) 255b for the link portions between the first member 51, the second member 52, and the third member 53. In this case, the outer circular portion 255a is fixed to one link portion, and a shaft component 254 is fitted in the inner circular portion 255b, and this shaft component 254 is then fixed to the other link portion. According to the structure, because the link is made such that the relative positions in the up-down directions of the exposure apparatus EX are regulated, while relative movement in directions other than the up-down directions of the exposure apparatus EX is possible, it is possible to keep the rigidity of the overall linking component 35 to a low level in directions other than the up-down directions of the exposure apparatus EX, while maintaining the rigidity thereof in the up-down direction of the exposure apparatus EX.

Furthermore, in the first embodiment, the sliding bearing 52c provided on the circular portion 52b has a spherical bearing surface with the diameter r2 larger than the diameter r1 of the spherical member 51e. However, the sliding bearing 52c can have a planer bearing surface. In this case, the spherical member 51e can be inserted into an elastic member of a cylindrical rubber and the like which is extended along a direction substantially parallel to the Z axis so as to be surrounded by the elastic member. When Hertz contact stress has no influence, the spherical members or the cylindrical members can be contact with each other so that a point contact or a line contact can be made up.

In the configuration in each embodiment, the relative movement between two members has a linearly movement and is assumed to be distinguish from a state in which the two members can be rotatable. In one example where a chain is used as a suspension component, adjacent members for constituting the chain (a first member and a second member) have a relative position between them regulated in the Z direction, and are rotatable about an axis. However, relative positions between the above-described adjacent members in X direction and Y direction are also regulated. Meanwhile, in each embodiment, for example, when the relative position between the first member and the second member in the Z direction is regulated, they can be relatively moved in at least one direction of the X and Y directions being different from the Z direction, Alternatively or also, they can be relatively moved in two directions of the X and Y directions or the other direction (e.g., the every direction on the XY plane).

In a structure in which the first member 151, the second member 152, and the third member 153 are in linear contact (i.e., in the second embodiment), it is also possible to employ a structure in which at least one of these three components has a hinge mechanism and is linked to another component via this hinge mechanism, and it is also possible to employ a structure in which these three components are linked via bearing mechanisms.

In the above-described structure, each of the linking components 35A to 35C has two link sections of a first link section where the first member 51 and the second member are linked together and a second link section where the second member and the third member are linked together. However, it is not limited to this. In one example, each of them has one link section. Or, a link section having another structure can additionally be applied.

In each embodiment, the lens barrel 17 of the exposure apparatus EX is suspended by the linking components 35A to 35C and is supported by the frame portion 18. However, it is not limited to this. In one example, in addition to the lens barrel 17, the measurement mount 15 is suspended and supported by use of linking components, or the other members can be suspended and supported by use of the same.

Note that in each of the above described embodiments, an example is described in which a semiconductor wafer which is used to manufacture a semiconductor device is exposed, however, in addition to this, the same description can also apply when a glass substrate which is used for a display device, a ceramic wafer which is used for a thin-film magnetic head, or an original plate (i.e., synthetic quartz or silicon wafer) of a mask or reticle which is used in an exposure apparatus, or the like is being exposed.

As the exposure apparatus EX, in addition to a step-and-scan type of scanning exposure apparatus (i.e., a scanning stepper) which makes a scanning exposure of a pattern on a reticle R while moving the reticle R and a wafer W in synchronization, it is also possible to use a step-and-repeat type of projection scanning device (i.e., a stepper) that collectively exposes the pattern on the reticle R while the reticle R and wafer W are static, and moves the wafer W in sequential steps. Moreover, the present invention can also be applied to a step-and-stitch type of exposure apparatus in which at least two patterns are partially superimposed and transferred onto a wafer W.

The type of exposure apparatus EX that is used is not limited to an exposure apparatus for manufacturing a semiconductor device that exposes a semiconductor device pattern onto a wafer W, and the present invention may also be broadly applied to exposure apparatuses for manufacturing liquid crystal display elements or manufacturing displays and the like, and to exposure apparatuses for manufacturing thin-film magnetic heads, image pickup elements (CCD), or reticles and masks, and the like.

As the light source for an exposure apparatus in which the present invention is used, not only is it possible to use a KrF excimer laser (having a wavelength of 248 nm), an ArF excimer laser (having a wavelength of 193 nm), an F2 laser (having a wavelength of 157 nm and the like, but it is also possible to use g-rays (having a wavelength of 436 nm) or i-rays (having a wavelength of 365 nm). Furthermore, the magnification system of the projection optical system may not only be a reducing system, but may also be either an equal magnification system, or an enlarging system. Moreover, in the above described embodiments, a reflective-refractive type of projection optical system is used as an example, however, the present invention is not limited to this and can also be applied to a refractive type of projection optical system in which the optical axis of the projection optical system (i.e., the center of the reticle) and the center of the projection area are set in different positions.

Moreover, the present invention has been applied to what is known as an immersion exposure apparatus in which a space between the projection optical system and the substrate is filled in localized portions with a liquid, and this immersion exposure method is disclosed in, for example, PCT International Publication No. WO 99/49504. Furthermore, the present invention can also be applied to an immersion exposure apparatus in which exposure is performed with the entire surface of the substrate which is to be exposed being immersed in the liquid, as is disclosed in, for example, Japanese Patent Application Publication Nos. H06-124873 A and H10-303114 A, and in U.S. Pat. No. 5,825,043.

The present invention can also be applied to a twin stage type of exposure apparatus that is provided with a plurality of substrate stages (i.e., wafer stages). The structure and exposure operations of a twin stage type of exposure apparatus are disclosed in, for example, Japanese Patent Application Publication Nos. H10-163099 A and H10-214783 A (corresponding to U.S. Pat. Nos. 6,590,634; 6,400,441; 6,549,269; and 6,590,634), Published Japanese Translation No. 2000-505958 of PCT International Publication (corresponding to U.S. Pat. No. 5,969,441), U.S. Pat. No. 6,208,407, and the like. Furthermore, the present invention may also be applied to Japanese Patent Application No. 2004-168481 for which application has already been made by the applicants of the present specification.

Moreover, an exposure apparatus in which the present invention is applied is manufactured by assembling various subsystems which include the respective component elements described within the range of the claims of the present specification such that they have a predetermined mechanical accuracy, electrical accuracy and optical accuracy. In order to secure these levels of accuracy, both before and after the assembly steps, adjustments to achieve optical accuracy in the various optical systems, adjustments to achieve mechanical accuracy in the various mechanical systems, and adjustments to achieve electrical accuracy in the various electrical systems are made. The assembly step to assemble an exposure apparatus from the various subsystems includes making mechanical connections, electrical circuit wiring connections, and air pressure circuit tube connections and the like between the various subsystems. Prior to the assembly step to assemble an exposure apparatus from the various subsystems, it is of course necessary to perform assembly steps to assemble the respective individual subsystems. Once the assembly step to assemble an exposure apparatus from the various subsystems has ended, comprehensive adjustments are made so as to secure various levels of accuracy in the exposure apparatus as a whole. Note that it is desirable for the manufacturing of the exposure apparatus to be conducted in a clean room in which temperature and cleanliness and the like are controlled.

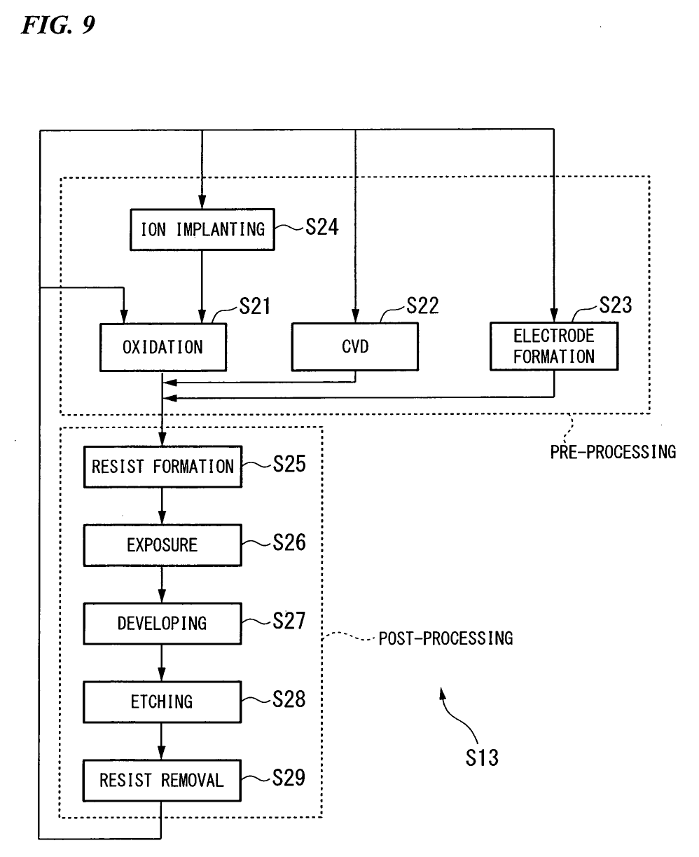

Next, an embodiment of a method of manufacturing a micro device in which the exposure apparatus and exposure method according to the embodiments of the present invention are used in a lithographic step will be described. FIG. 9 shows a flow chart of an example of the manufacture of a micro device (i.e., a semiconductor chip such as an IC or LSI, a liquid crystal panel, a CCD, a thin film magnetic head, a micro machine, and the like).

Firstly, in step S10 (a design step), the functions and performance of the micro device (for example, the circuit design of a semiconductor device and the like) are designed, and a pattern is designed in order to achieve these functions. Next, in step S11 (a mask manufacturing step), a mask (reticle) on which the designed circuit pattern has been formed is manufactured. Meanwhile, in step S12 (a wafer manufacturing step), a wafer is manufactured using a material such as silicon or the like.

Next, in step S13 (a wafer processing step), using the mask and wafer prepared in steps S10 to S12, as is described below, an actual circuit or the like is formed on the wafer using lithographic technology. Next, in step S14 (a device assembly step), a device is assembled using the wafer that was processed in step S13. In this step S14, steps such as a dicing step, a bonding step, a packaging step (i.e., enclosure in a chip), and the like are included according to requirements. Finally, in step S15 (an inspection step), inspections such as an operation verification test, a durability test, and the like are performed on the micro device manufactured in step S14. After passing through these steps, the micro device is completed, and the completed device is shipped.

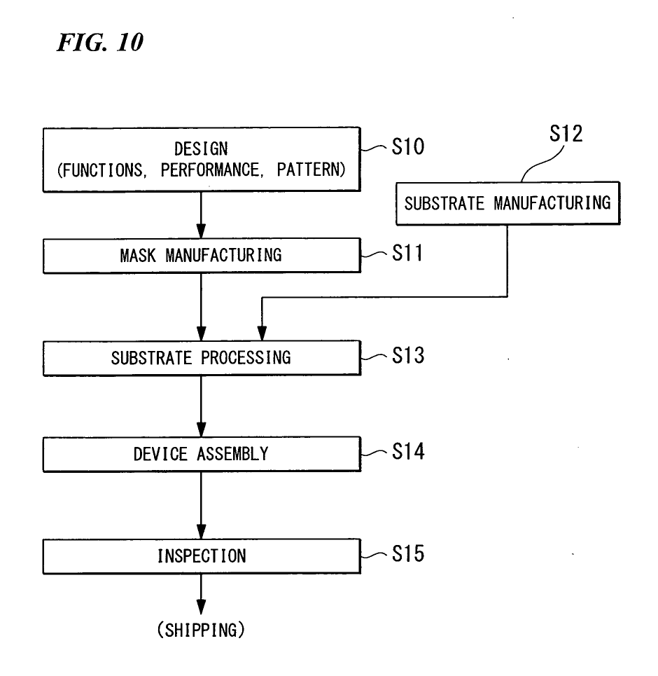

FIG. 10 shows an example of the specific processes of step S13 in the case of a semiconductor device.

In step S21 (an oxidation step), a surface of a wafer is oxidized. In step S22, (a CVD step), a non-conductive film is formed on the surface of the wafer. In step S23 (an electrode formation step), an electrode is formed on the wafer by vapor deposition. In step S24 (an ion implanting step), ions are implanted in the wafer. Each of the steps S21 to S24 formulate the pre-processing steps for each stage of the wafer processing, and may be selected and conducted in accordance with the processing required in each stage.

In each stage of the wafer processing, when the above described pre-processing has ended, post-processing steps such as those described below are performed. In these post-processing steps, firstly, in step S25 (a resist formation step), a photosensitive agent is coated on a wafer. Next, in step S26 (an exposure step), the circuit pattern on the mask is transferred onto the wafer using the above described lithographic system (i.e., exposure apparatus) and exposure method. Next, in step S27 (a developing step), the exposed wafer is developed, and in step S28 (an etching step), exposed components in portions other than those portions where resist is present are removed by etching. In step S29 (a resist removal step), unnecessary resist when the etching has been completed is removed. By repeating this pre-processing and post-processing, a multiple layer circuit pattern is formed on the wafer.

The present invention can be applied not only to micro devices such as semiconductors, but also to exposure apparatuses which transfer a circuit pattern from a mother reticle onto a glass substrate or silicon wafer or the like in order to manufacture a reticle or mask which is used in a light exposure apparatus, an EUV exposure apparatus, an X-ray exposure apparatus, or an electron beam exposure apparatus or the like. Here, in an exposure apparatus which uses deep ultraviolet (DUV) or vacuum ultraviolet (VUV) or the like, generally, a transmission type of reticle is used, and quartz glass, fluorine-doped quartz glass, fluorite, magnesium fluoride, or crystal or the like can be used for the reticle substrate. Moreover, in proximity type X-ray exposure apparatuses and electron beam exposure apparatuses and the like, a transmission type of mask (i.e., a stencil mask) is used, and a silicon wafer or the like can be used for the mask substrate. Note that this type of exposure apparatus is disclosed in WO 99/34255, WO 99/50712, WO 99/66370, Japanese Patent Application Publication Nos. H11-194479 A, 2000-12453 A, and 2000-29202 A.

What is claimed is:

1. A suspension apparatus comprising:
a linking component which is used to suspend and support an object,
wherein the linking component comprises a first member which is connected to the object, and a second member which is linked to the first member, and
the first member and the second member are linked together such that a relative position of each in a first direction is regulated, while relative movement between the first member and the second member in a second direction which is different from the first direction is possible.

2. The suspension apparatus according to claim 1, wherein the first member and the second member are linked together so as to be capable of relatively moving with each other also in a third direction which is different from the first direction and the second direction.

3. The suspension apparatus according to claim 1, wherein the first member and the second member are linked so as to be in point contact with each other.

4. The suspension apparatus according to claim 1, wherein
one of the first member and the second member has a sliding bearing which has a spherical bearing surface, and
the other one of the first member and the second member has a spherical member which is supported by the bearing surface, and has a spherical surface whose diameter is smaller than a diameter of the spherical surface of the bearing surface.

5. The suspension apparatus according to claim 1, wherein the first member and the second member are linked so as to be in linear contact with each other.

6. The suspension apparatus according to claim 5, wherein at least one of the first member and the second member has a hinge mechanism.

7. The suspension apparatus according to claim 5, wherein the first member and the second member are linked via a bearing mechanism.

8. The suspension apparatus according to claim 1, wherein at least one of the first member and the second member has a rod-shaped portion.

9. The suspension apparatus according to claim 1, wherein there are three linking components.

10. The suspension apparatus according to claim 1, wherein the linking component comprises a third member which is linked to the second member, and the second member and the third member are linked together such that a relative position in the first direction are regulated, while relative movement between the second member and the third member in the second direction is possible.

11. The suspension apparatus according to claim 1, further comprising:
an air mount for supporting the linking component,
wherein the air mount comprises a housing member which forms a predetermined space, a movable member which is supported so as to be able to move in the first direction relative to the housing member and which a part of which penetrates an interior of the space and protrudes to an outside of the housing member, and a sealing member which is provided between the housing member and the movable member and which seals off the space, and
the movable member and the linking component are connected together.

12. The suspension apparatus according to claim 11, wherein the movable member is integrally connected to the third member of the linking component.

13. The suspension apparatus according to claim 1, wherein the object comprises a projection optical system.

14. The suspension apparatus according to claim 1, wherein the object is an interferometer.

15. The suspension apparatus according to claim 1, wherein the object comprises a measurement component which is provided with a measurement device.

16. An exposure apparatus which is provided with the suspension apparatus according to claim 1.
